(19) United States
(12) Patent Application Publication
(10) Pub. No.: US 2024/0079185 A1
(43) Pub. Date: Mar. 7, 2024

(54) DYE-SENSITIZED SOLAR CELL AND METHOD FOR MANUFACTURING DYE-SENSITIZED SOLAR CELL

(71) Applicant: SHARP KABUSHIKI KAISHA, Osaka (JP)

(72) Inventors: Uran SATO, Osaka (JP); HIROKAZU ICHINOSE, Osaka (JP); ATSUSHI FUKUI, Osaka (JP)

(21) Appl. No.: 18/227,274

(22) Filed: Jul. 27, 2023

(30) Foreign Application Priority Data
Aug. 19, 2022 (JP) 2022-131106

(51) Int. Cl. H01G 9/20; H01L 31/18

(52) U.S. Cl. CPC H01G 9/2004; H01G 9/2059; H01L 31/18; H01G 9/2031

(57) ABSTRACT

A dye-sensitized solar cell includes: a first electrode including a porous semiconductor layer supporting a dye; a second electrode serving as a counter electrode of the first electrode; and an electrolyte solution filled between the first electrode and the second electrode. The electrolyte solution contains a silane coupling agent.

### CROSS-REFERENCE TO RELATED APPLICATION

The present application claims priority from Japanese Application JP2022-131106, the content of which is hereby incorporated by reference into this application.

### BACKGROUND OF THE INVENTION

### 1. Field of the Invention

The present disclosure relates to a dye-sensitized solar cell and a method for producing the dye-sensitized solar cell.

### 2. Description of the Related Art

Known solar cells for converting sunlight into electric power include solar cells using crystalline silicon substrates and thin-film silicon solar cells. A solar cell with a crystalline silicon substrate uses a silicon substrate, and a thin-film silicon solar cell is produced with various kinds of semiconductor producing gases and apparatuses. Hence, the production costs tend to increase for both types of the cells. On the other hand, dye-sensitized solar cells are also proposed. These cells omit, for example, costly silicon substrates, and are implemented with application of photoinduced electron transfer of a metal complex. When a dye-sensitized solar cell is irradiated with light, the photoelectric conversion unit generates electrons. The electrons move to one of the electrodes and pass through an external electric circuit. After that, the electrons are transported through the other opposing electrode to ions in an electrolyte solution, and return to the photoelectric conversion unit. This is how electric energy is extracted.

Japanese Patent Application No. 2013-012404 discloses a technique that involves processing to coat a substrate having a semiconductor layer with a dye solution delivered in the form of droplets. After that, the technique involves solvent removing processing to evaporate and remove the solvent from the dye solution on the semiconductor layer, and rinse processing to rinse excess dye attached to the surface of the semiconductor layer. Hence, the technique allows the dye to be adsorbed onto the semiconductor layer.

As to solar cells, improvement in cell characteristics is a permanent challenge, and dye-sensitized solar cells are also always required of improvement in cell characteristics.

The present disclosure is intended to provide a dye-sensitized solar cell capable of achieving improvements in cell characteristics and a method for producing the dye-sensitized solar cell.

In order to overcome the above challenge, a dye-sensitized solar cell according to a first aspect of the present disclosure includes: a first electrode including a porous semiconductor layer supporting a dye; a second electrode serving as a counter electrode of the first electrode; and an electrolyte solution filled between the first electrode and the second electrode, wherein the electrolyte solution contains a silane coupling agent.

Thanks to the above configuration, the silane coupling agent added to the electrolyte solution can improve cell characteristics of the dye-sensitized solar cell.

Furthermore, as to the dye-sensitized solar cell, in the electrolyte solution, the silane coupling agent may have a concentration in a range of 5 to 30 vol %.

Thanks to the above configuration, the silane coupling agent sufficiently contributes to improvement in cell characteristics of the dye-sensitized solar cell. Furthermore, the configuration improves solubility of the silane coupling agent in the electrolyte solution.

Moreover, as to the dye-sensitized solar cell, the silane coupling agent contained in the electrolyte solution may have three alkoxy groups.

In order to overcome the above challenge, a method for producing a dye-sensitized solar cell is a second aspect of the present disclosure. The dye-sensitized solar cell includes: a first electrode including a porous semiconductor layer supporting a dye; a second electrode serving as a counter electrode of the first electrode; and an electrolyte solution filled between the first electrode and the second electrode. The method includes: a step of sealing a region between the first electrode and the second electrode, using a sealing material; and a step of encapsulating the electrolyte solution in the sealed region, the electrolyte solution containing a silane coupling agent.

Furthermore, as to the method for producing the dye-sensitized solar cell, in the electrolyte solution to be encapsulated in the region, the silane coupling agent may have a concentration in a range of 5 to 30 vol %.

In order to overcome the above challenge, a method for producing a dye-sensitized solar cell is a third aspect of the present disclosure. The dye-sensitized solar cell includes: a first electrode including a porous semiconductor layer supporting a dye; a second electrode serving as a counter electrode of the first electrode; and an electrolyte solution filled between the first electrode and the second electrode. The method includes: a step of forming the porous semiconductor layer and a sealing material on a first substrate having the first electrode, the porous semiconductor layer not supporting the dye yet and the sealing material being formed into a shape of a frame; a step of delivering a dye electrolyte solution in droplets onto the porous semiconductor layer within the frame of the sealing material, the dye electrolyte solution containing a dye to be supported on the porous semiconductor layer and a silane coupling agent; and, after the step of delivering the dye electrolyte solution, a step of attaching a second substrate to the sealing material to seal a region between the first electrode and the second electrode, the second substrate having the second electrode.

Furthermore, as to the method for producing the dye-sensitized solar cell, in the dye electrolyte solution to be delivered onto the porous semiconductor layer, the silane coupling agent may have a concentration in a range of 5 to 20 vol %.

As to the dye-sensitized solar cell and the method for producing the dye-sensitized solar cell of the present disclosure, the silane coupling agent is added to the electrolyte solution. Such a feature achieves an advantageous effect of improving cell characteristics of the dye-sensitized solar cell.

### BRIEF DESCRIPTION OF THE DRAWINGS

FIG. 1 is a cross-sectional view schematically illustrating a step of a method for producing a dye-sensitized solar cell according to Embodiment 1 of the present disclosure;

FIG. 2 is a cross-sectional view schematically illustrating a post-process of FIG. 1;

FIG. 3 is a cross-sectional view schematically illustrating a post-process of FIG. 2;

FIG. 4 is a cross-sectional view schematically illustrating a post-process of FIG. 3;

FIG. 5 is a cross-sectional view schematically illustrating a post-process of FIG. 4;

FIG. 6 is a cross-sectional view schematically illustrating a dye-sensitized solar cell obtained after a post-process of FIG. 5;

FIG. 7 is a graph (I-V curve) showing electrical characteristics of a dye-sensitized solar cell of the present disclosure and electrical characteristics of a conventional dye-sensitized solar cell for comparison.

FIG. 8 is a cross-sectional view schematically illustrating a step of a method for producing a dye-sensitized solar cell according to Embodiment 2 of the present disclosure; and

FIG. 9 is a cross-sectional view schematically illustrating a post-process of FIG. 8.

### DETAILED DESCRIPTION OF THE INVENTION

### Embodiment 1

Described below is an example of a method for producing a dye-sensitized solar cell of the present disclosure.

A method for producing a dye-sensitized solar cell of the present disclosure is directed to a dye-sensitized solar cell including: a first electrode including a porous semiconductor layer supporting a dye; a second electrode serving as a counter electrode of the first electrode; and an electrolyte solution filled between the first electrode and the second electrode. In the dye-sensitized solar cell, the first electrode is an electrode substrate including a porous semiconductor layer supporting at least a photosensitizing dye (hereinafter simply referred to as “dye”), and further including a transparent conductive layer. This first electrode is also referred to as a photoelectrode. Furthermore, the second electrode is an electrode that functions as a counter electrode of the photoelectrode; namely, the first electrode. The second electrode is also referred to as a counter electrode, and includes at least a counter-electrode conductive layer. The second electrode may further include a catalyst layer. Moreover, the counter-electrode conductive layer may also serve as a catalyst layer.

A plurality of dye-sensitized solar cells are integrated into a module. The module includes, for example, cells arranged side by side and electrically connected in series or in parallel. Here, for example, the transparent conductive layer formed on the substrate is shared among the cells so that the electrode of one cell can be connected to another cell.

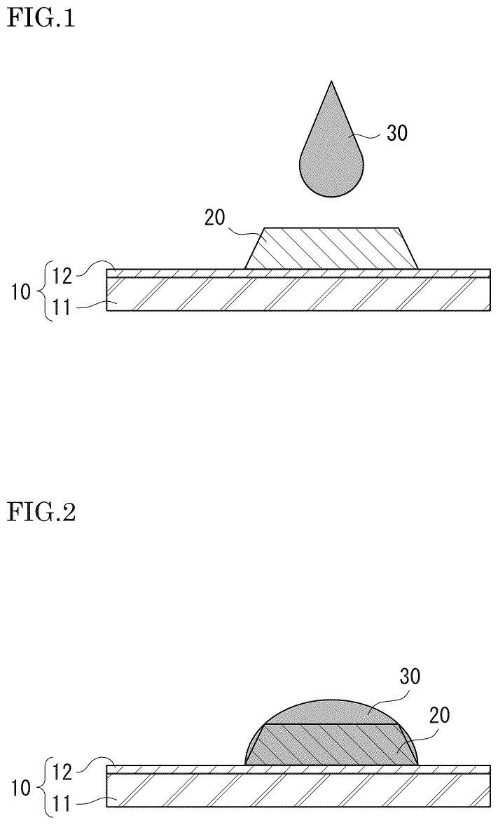

FIGS. 1 to 5 are cross-sectional views schematically and sequentially illustrating steps of a method for producing a dye-sensitized solar cell according to Embodiment 1.

As illustrated in FIG. 1, an electrode substrate (a first substrate) 10 includes: a transparent substrate 11; and a transparent conductive layer 12 formed on the transparent substrate 11. Provided on the transparent conductive layer 12 is a porous semiconductor layer 20. The transparent substrate 11 is a light-transparent (light-transmitting) non-conductive sheet member capable of transmitting light emitted on the light-receiving surface. The transparent substrate 11 is formed of, for example, glass, transparent resin, or silicon.

The transparent conductive layer 12 is made of a light-transparent material, just like the transparent substrate 11 is. The transparent conductive layer 12 is the first electrode that conducts electricity. The transparent conductive layer 12 can be made of at least one material selected from the group consisting of, for example, indium tin oxide (ITO), tin oxide (SnO₂), fluorine-doped tin oxide (FTO), and zinc oxide (ZnO). The transparent conductive layer 12 has a thickness of preferably, for example, 0.02 μm or more and 5.0 μm or less.

The porous semiconductor layer 20 contains a semiconductor material. The porous semiconductor layer 20 may be formed into various shapes such as a bulk, particles, and a layer having a large number of micropores. Preferably, the porous semiconductor layer 20 has a porous structure capable of supporting a dye. The porous semiconductor layer 20 is made of at least one semiconductor material selected from the group consisting of, for example, titanium oxide, zinc oxide, tin oxide, iron oxide, niobium oxide, cerium oxide, tungsten oxide, barium titanate, strontium titanate, cadmium sulfide, lead sulfide, zinc sulfide, indium phosphide, copper indium sulfide (CuInS₂), CuAlO₂, and SrCu₂O₂.

Among these materials, titanium oxide is preferably used for the porous semiconductor layer 20. The titanium oxide includes, for example, various types of titanium oxides such as anatase titanium oxide, rutile titanium oxide, amorphous titanium oxide, metatitanic acid, and orthotitanic acid, titanium hydroxide, or hydrous titanium oxide. These materials may be used alone or in a mixture. Furthermore, the porous semiconductor layer 20 can be made of fine particles of titanium oxide.

A crystal system of the semiconductor may be either a monocrystalline system or a polycrystalline system. In view of stability, ease of crystal growth, and production costs, a polycrystalline semiconductor is preferable. Preferably used are polycrystalline semiconductor fine particles either in nanoscale or in microscale. Fine particles of titanium oxide can be produced by either: liquid phase synthesis using hydrothermal synthesis or sulfuric acid; or gas phase synthesis.

The semiconductor fine particles may be a mixture of fine particles having two or more particle sizes and made of a single semiconductor compound or different semiconductor compounds. The semiconductor fine particles in a large particle size scatter incident light, thereby contributing to an increase in light capturing rate. The semiconductor fine particles in a small particle size have many adsorption points, thereby capable of adsorbing the dye in a large amount. The porous semiconductor layer 20 has a thickness of preferably, for example, 0.1 μm or more and 100.0 μm or less.

As the dye to be supported on the porous semiconductor layer 20, one or more kinds of organic dyes and metal complex dyes having absorption in a visible light region or an infrared light region can be selectively used. The organic dyes may be at least one dye selected from the group consisting of, for example, an azo-based dye, a quinone-based dye, a quinone-imine-based dye, a quinacridone-based dye, a squarylium-based dye, a cyanine-based dye, a merocyanine-based dye, a triphenylmethane-based dye, a xanthene-based dye, a porphyrin-based dye, a perylene-based dye, an indigo-based dye, and a naphthalocyanine-based dye.

A metal complex dye is a coordinate bond of molecules and metal. The molecules are of, for example, a porphyrin-based dye, a phthalocyanine-based dye, a naphthalocyanine-based dye, a bipyridine-based dye, or a terpyridine-based dye. The metal can be at least one selected from the group containing of, for example, Cu, Ni, Fe, Co, V, Sn, Si, Ti, Ge, Cr, Zn, Ru, Mg, Al, Pb, Mn, In, Mo, Y, Zr, Nb, Sb, La, W, Pt, TA, Ir, Pd, Os, Ga, Tb, Eu, Rb, Bi, Se, As, Sc, Ag, Cd, Hf, Re, Au, Ac, Tc, Te, and Rh. The metal complex dye is preferably a phthalocyanine-based dye, a bipyridine-based dye, or a terpyridine-based dye to which metal is coordinated. A particularly preferable metal complex dye to be used is a ruthenium-bipyridine complex dye.

Such a dye is dissolved in a dye solution 30. As illustrated in FIG. 1, the dye solution 30 is delivered in droplets onto the porous semiconductor layer 20 on the electrode substrate 10 (a dripping step). The dye solution 30 may contain any solvent as long as the dye can be dissolved in the solvent. Examples of the solvent include: alcohols such as ethanol; ketones such as acetone; ethers such as diethyl ether and tetrahydrofuran; cyclic esters such as γ-butyrolactone and ε-caprolactone; cyclic amides such as 1-methyl-2-pyrrolidone; and water. The solvent can be a mixture of two or more kinds of solvents. A dye concentration of the dye solution 30 can be appropriately adjusted, depending on types of the dye and the solvent to be used.

In this dripping step, the dye solution 30 is preferably kept from adhering to the transparent conductive layer 12 around the porous semiconductor layer 20. Hence, the dripping step is carried out preferably with, for example, the surface of the transparent conductive layer 12 made water-repellent, or with the periphery of the porous semiconductor layer 20 covered with a sealing material before the dripping step. In addition, the amount of the dye solution 30 to be delivered in droplets is set equivalent to the volume of the porous semiconductor layer 20. Hence, the dye solution 30 may be kept from adhering to the transparent conductive layer 12 outside the porous semiconductor layer 20.

Next, as illustrated in FIG. 2, the porous semiconductor layer 20 is impregnated with the dye solution 30 delivered in droplets (an impregnation step). Then, the dye solution 30 is left on the porous semiconductor layer 20, so that the dye in the dye solution 30 is adsorbed onto the porous semiconductor layer 20. In order to reduce uneven adsorption of the dye solution 30, the impregnation of the porous semiconductor layer 20 preferably takes for approximately 5 to 30 minutes.

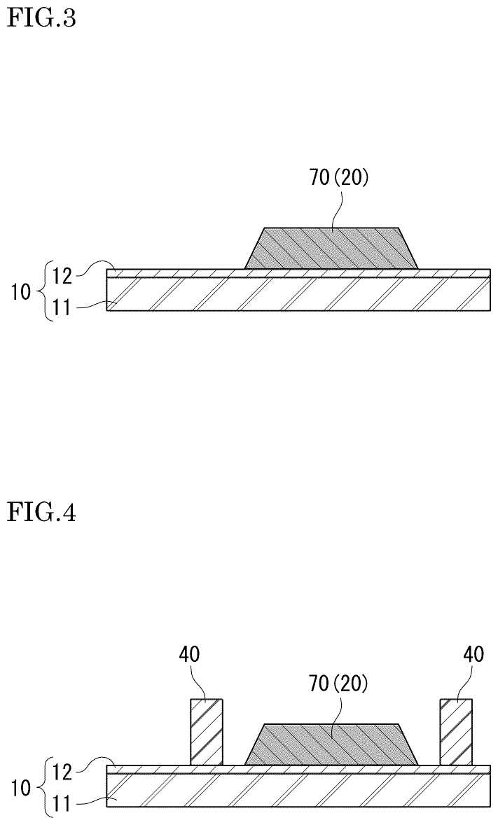

Next, as illustrated in FIG. 3, the porous semiconductor layer 20 impregnated with the dye solution 30 is dried (a drying step). The porous semiconductor layer 20 illustrated in FIG. 2 is impregnated with the dye solution 30 delivered in droplets, and the delivered dye solution remains on the porous semiconductor layer 20. At the drying step, the electrode substrate 10, which is provided with the porous semiconductor layer 20 impregnated with the dye solution 30, is either vacuum dried or heat dried. Hence, the dye solution 30 is dried. The heat drying is preferably carried out at a temperature of, for example, approximately 50° C. At the drying step, the dye in the dye solution 30 is deposited on the porous semiconductor layer 20. After that, rinsing processing is carried out to rinse excess dye adhering to the surface of the porous semiconductor layer 20. Hence, as illustrated in FIG. 3, the porous semiconductor layer 20 with the dye adsorbed thereto successfully forms a photoelectric conversion unit (a porous semiconductor layer supporting the dye) 70.

Note that a technique to adsorb the dye onto the porous semiconductor layer 20 and to form the photoelectric conversion unit 70 shall not be limited to the above technique to deliver the dye solution 30 in droplets onto the porous semiconductor layer 20. For example, the electrode substrate 10 (in the state illustrated in FIG. 1) having the porous semiconductor layer 20 may be immersed in the dye solution 30 and left still for a long time so that the dye is adsorbed onto the porous semiconductor layer 20.

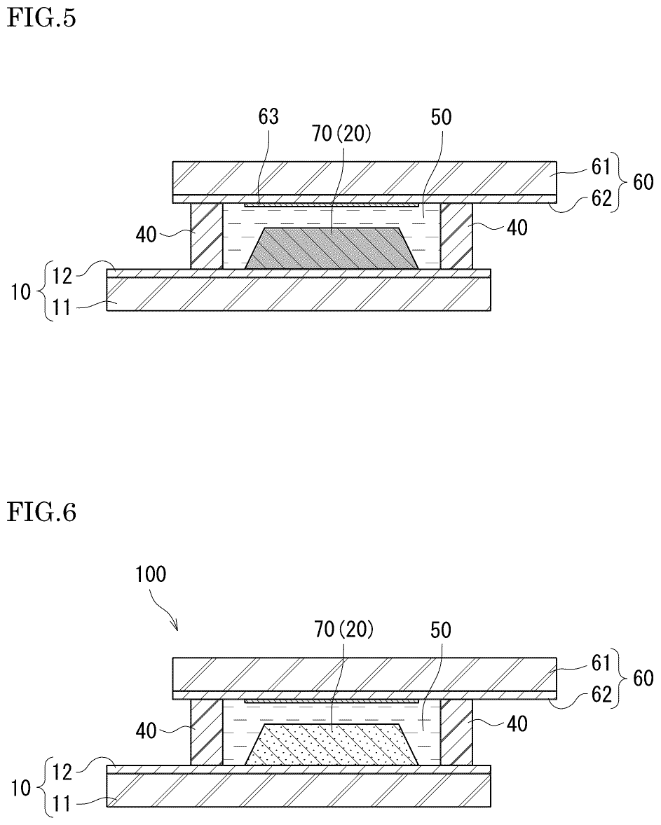

Next, as illustrated in FIG. 4, a sealing material 40 is provided on the transparent conductive layer 12 of the electrode substrate 10 (a sealing material providing step). The sealing material 40 is formed into a shape of a frame on an outer peripheral portion of the electrode substrate so as to surround the porous semiconductor layer 20. Furthermore, as illustrated in FIG. 5, a counter-electrode substrate (a second substrate) 60, which includes a counter-electrode conductive layer 62 as a second electrode, is provided across from the transparent conductive layer 12 of the electrode substrate 10. The sealing material 40 is disposed between the transparent conductive layer 12 of the electrode substrate 10 and the counter electrode conductive layer 62, and seals in a watertight manner a region between the transparent conductive layer 12 and the counter-electrode conductive layer 62. The sealing material 40 can be formed of a sealing material highly adhesive and resistant to a chemical agent and heat.

As illustrated in FIG. 5, the counter-electrode substrate 60 includes: a transparent substrate 61 made of a sheet material transparent to light and non-conductive of electricity; and a counter-electrode conductive layer 62 transparent to light and conductive of electricity. The transparent substrate 61 and the counter-electrode conductive layer 62 of the counter electrode substrate 60 can be the same in configuration as the transparent substrate 11 and the transparent conductive layer 12 included in the electrode substrate 10.

On the counter-electrode conductive layer 62, a catalyst layer 63 is additionally stacked. The catalyst layer 63 contains catalytic metal particles. The catalyst layer 63 may be stacked with any given technique, such as screen printing, vapor deposition, or sputtering.

Next, as illustrated in FIG. 5, an electrolyte solution 50 is encapsulated in a region provided between the electrode substrate 10 and the counter electrode substrate 60 and sealed with the sealing material 40. In encapsulating the electrolyte solution 50, for example, the counter-electrode substrate 60 or the sealing material 40 is previously provided with an opening for injecting the electrolyte solution 50. After the electrolyte solution 50 is injected, the opening is sealed with, for example, a sealing material. Hence, the electrolyte solution 50 is successfully encapsulated. Thus, a space between the electrode substrate 10 and the counter-electrode substrate 60 is filled with the electrolyte solution 50. Here, as to the dye-sensitized solar cell according to Embodiment 1, a silane coupling agent is previously added to the electrolyte solution 50. The reason for adding the silane coupling agent to the electrolyte solution 50 will be described later in detail. The electrolyte solution 50 is a liquid containing a redox couple. The electrolyte solution 50 may be, for example, a liquid made of a redox couple and a solvent in which the redox couple can be dissolved, a liquid made of a redox couple and a molten salt in which the redox couple can be dissolved, or a liquid made of a redox couple, and a solvent and a molten salt in which the redox couple can be dissolved.

The solvent of the electrolyte solution 50 is preferably a solvent containing at least one selected from the group consisting of, for example, a carbonate compound such as propylene carbonate, a nitrile compound such as acetonitrile, alcohols such as ethanol, cyclic esters such as γ-butyrolactone and ε-caprolactone, cyclic amides such as 1-methyl-2-pyrrolidone, water, and an aprotic polar substance. As the solvent, the cyclic esters or the cyclic amides are preferably used alone of in a mixture. In this manner, the dye-sensitized solar cell 100 having the structure illustrated in FIG. 6 can be obtained. In the dye-sensitized solar cell 100, the silane coupling agent added to the electrolyte solution 50 is contained as a silane coupling agent or a product of the silane coupling agent.

The dye-sensitized solar cell 100 having the structure illustrated in FIG. 6 includes: the sealing material 40 formed into a shape of a frame so as to surround the photoelectric conversion portion 70; and the electrolyte solution 50 encapsulated in a region provided between the electrode substrate 10 and the counter electrode substrate 60 and sealed with the sealing material 40. Here, in studying reliability of the sealing material 40, the inventors of the present invention conducted an experiment to examine whether a component leaking from the sealing material 40 into the electrolyte solution 50 would have affected the sealing reliability. Specifically, the study was conducted in such a manner that a silane coupling agent, which is a low-molecular component contained in the sealing material 40, was intentionally added to the electrolyte solution 50. Note that the silane coupling agent in the sealing material 40 is used to enhance adhesiveness between: the sealing material 40; and the transparent conductive layer 12 and the counter electrode conductive layer 62. Furthermore, in this reliability study, a concentration of the silane coupling agent added to the electrolyte solution 50 was sufficiently greater than the amount of the silane coupling agent expected to leak out of the sealing material 40.

In the reliability study described above, the silane coupling agent added to the electrolyte solution 50 exhibited not adverse effects but improvements in cell characteristics (short-circuit current density, open-circuit voltage, fill factor, and conversion efficiency). In the dye-sensitized solar cell 100 of the present disclosure, thanks to this discovery, a silane coupling agent is added to the electrolyte solution 50 so as to improve cell characteristics of the dye-sensitized solar cell 100.

One of the reasons why the dye-sensitized solar cell 100 of the present disclosure exhibits improvements in cell characteristics is that the silane coupling agent added to the electrolyte solution 50 probably forms a coating film on the porous semiconductor layer 20. That is, the inside of the sealing region (the inside of the cell) in the dye-sensitized solar cell 100 is impregnated with the electrolyte solution 50. After that, the silane coupling agent quickly and uniformly spreads over, and wets, the entire porous semiconductor layer 20. The silane coupling agent bonds to the porous semiconductor layer 20 to form a coating film on the porous semiconductor layer 20. This coating film serves as an insulating layer, and can probably block a leakage of the electrons from the porous semiconductor layer 20 into the electrolyte solution 50.

As to the dye-sensitized solar cell 100 produced by the method of Embodiment 1, the dye is adsorbed onto the porous semiconductor layer 20, and after that, the electrolyte solution 50 with the silane coupling agent additionally contained is encapsulated. Hence, the coating film formed of the silane coupling agent and provided on the porous semiconductor layer 20 does not inhibit the dye adsorption onto the porous semiconductor layer 20. Furthermore, as to the silane coupling agent added to the electrolyte solution 50, not all the silane coupling agent forms the coating film on the porous semiconductor layer 20. Probably, some of the silane coupling agent forms the coating film and the rest remains dissolved in the electrolyte solution 50. Hence, the silane coupling agent in the produced dye-sensitized solar cell 100 simultaneously causes: a deposition reaction, as the coating film, from the electrolyte solution 50; and an elution reaction from the coating film to the electrolyte solution 50. These reactions stabilize in a state of equilibrium, thereby making it possible to stabilize the cell characteristics of the dye-sensitized solar cell 100.

The silane coupling agent to be added to the electrolyte solution 50 is represented by a structural formula (1). In the structural formula (1), R1 to R4 are selected from substituents such as an alkyl group, an aryl group, an alkoxy group, an amino group, an epoxy group, a methacrylic group, a halogen group, a halogenated alkyl group, a vinyl group, a mercapto group, a hydroxy group, a silyl group, and an acyloxy group. All of R1 to R4 may be selected from different substituents. Alternatively, R1 to R4 may contain two or more of the same substituents. Note that at least one or more of R1 to R4 are either an alkoxy group or an acyloxy group (R of the acyloxy group is CH₃→acetoxy group).

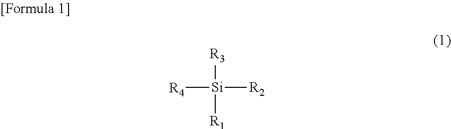

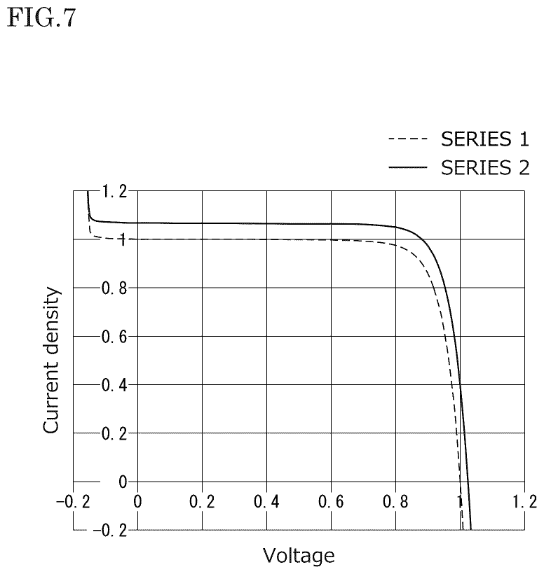

FIG. 7 is a graph (I-V curve) showing electrical characteristics (a series 2) of the dye-sensitized solar cell 100 of the present disclosure and electrical characteristics (a series 1) of a conventional dye-sensitized solar cell for comparison. Here, as to the dye-sensitized solar cell 100, fluorine-doped tin oxide (FTO) is used as the transparent conductive layer 12 and the counter-electrode conductive layer 62, poly(3,4 ethylenedioxythiophene) (PEDOT) is used as the catalyst layer 63, and titanium oxide is used as the porous semiconductor layer 20. Furthermore, in the present disclosure, as the silane coupling agent to be added to the electrolyte solution 50, triethoxypropylsilane represented by a structural formula (2) is used. The conventional dye-sensitized solar cell is different from the dye-sensitized solar cell 100 only in that the electrolyte solution of the former solar cell does not contain a silane coupling agent. The other conditions of the conventional dye-sensitized solar cell are the same as those of the dye-sensitized solar cell 100. The current and the voltage are measured while the dye-sensitized solar cells are irradiated with light having an illuminance of 500 lux.

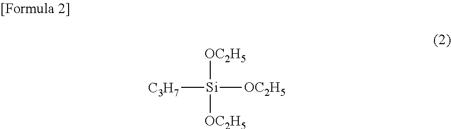

In the graph of FIG. 7, each of the numerical values on the vertical axis and the horizontal axis indicates a ratio with respect to a reference value. The reference value (=1) is an open-circuit voltage (a voltage at a current density of 0) and a short-circuit current density (a current density at a voltage of 0) of the conventional dye-sensitized solar cell.

As apparently seen from the graph of FIG. 7, the dye-sensitized solar cell 100 exhibits improvements in short-circuit current density and open-circuit voltage, compared with the conventional dye-sensitized solar cell. Furthermore, the graph of FIG. 7 also shows that the dye-sensitized solar cell 100 exhibits improvements in fill factor and conversion efficiency, compared with the conventional dye-sensitized solar cell. Specifically, the dye-sensitized solar cell 100 shows that the short-circuit current density is increased by 7%, the open-circuit voltage is increased by 2%, the fill factor is increased by 0.7%, and the conversion efficiency is increased by 10%. As can be seen, the dye-sensitized solar cell 100 improves its solar cell characteristics in all of the short-circuit current density, open circuit voltage, fill factor, and conversion efficiency, compared with the conventional dye-sensitized solar cell. In particular, in a comparison between the short-circuit current density and the open-circuit voltage, the short-circuit current density is greatly increased.

Note that, in Embodiment 1, the porous semiconductor layer 20 (that is, the photoelectric conversion unit 70) supporting the dye is sealed in the cell. After that, the electrolyte solution 50 is encapsulated in the cell. However, as a modification of such a feature, the porous semiconductor layer 20 not supporting the dye may be sealed in the cell. After that, a dye electrolyte solution (e.g., a dye electrolyte solution 52 in a second embodiment), which contains not only the silane coupling agent but also the dye, may be encapsulated in the cell.

### Embodiment 1A

As a modification of Embodiment 1, the steps after the drying step may be changed as follows. That is, the dye solution 30 is delivered in droplets onto the porous semiconductor layer 20, and the porous semiconductor layer 20 is impregnated with the dye solution 30. Then, the porous semiconductor layer 20 is dried. After that, the rinse processing is omitted and the sealing material providing step is carried out. After that, the electrolyte solution 50 is encapsulated in the region provided between the electrode substrate 10 and the counter-electrode substrate 60 and sealed with the sealing material 40. However, the rinse processing is omitted, such that the dye deposited on the porous semiconductor layer 20 dissolves in the electrolyte solution 50 (a dye dissolving step).

Here, a dye concentration of the dye solution 30 is preferably high in order to improve the adsorption function. In view of the amount of the dye solution 30 delivered in droplets and held onto the substrate and of the amount of the dye to be adsorbed onto the substrate, the dye concentration of the dye solution 30 is preferably, for example, 2 mmol/L or more. Furthermore, a solvent of the electrolyte solution 50 can preferably dissolve a dye of 1 mmol/L or more. More preferably, the solvent of the electrolyte solution 50 can dissolve a dye of 4 mmol/L to 8 mmol/L. At the dripping step, almost all of the dye solution 30, delivered in droplets onto the porous semiconductor layer 20, is left on the porous semiconductor layer 20. Hence, at the drying step, almost all of the dye, contained in the dye solution 30 delivered in droplets onto the porous semiconductor layer 20, can be deposited on the porous semiconductor layer 20. Thus, when the electrolyte 50 and the dye deposited on the porous semiconductor layer 20 are brought into contact with each other, the dye is dissolved in the solvent. Accordingly, the electrolyte 50 can become a dye-dissolving electrolyte.

Next, the dye dissolved in the electrolyte solution 50 is adsorbed onto the porous semiconductor layer 20 (a dye adsorption step). The dye is adsorbed preferably chemically. At the dye adsorption step, the porous semiconductor layer 20 may be heated. When the porous semiconductor layer 20 is heated, the movement of the dye is promoted. As a result, the dye can be easily adsorbed onto the porous semiconductor layer 20. Thus, the photoelectric conversion portion 70 can be formed with the dye adsorbed onto the porous semiconductor layer 20. As a result, the dye-sensitized solar cell 100 to be obtained can have the structure in FIG. 6.

In Embodiment 1A, the sealing material providing step follows the drying step. At the dripping step, the dye solution is delivered in droplets not to adhere to the transparent conductive layer 12 and, furthermore, the rinse processing is omitted. Such features can prevent contamination on the transparent conductive layer 12 of the electrode substrate 10 before the sealing material 40 is provided. Moreover, the sealing material 40 can be placed on the transparent conductive layer 12 that is clean and not contaminated with the dye solution 30. Such a feature ensures the sealing with the sealing material 40, thereby contributing to improvement in reliability.

### Embodiment 2

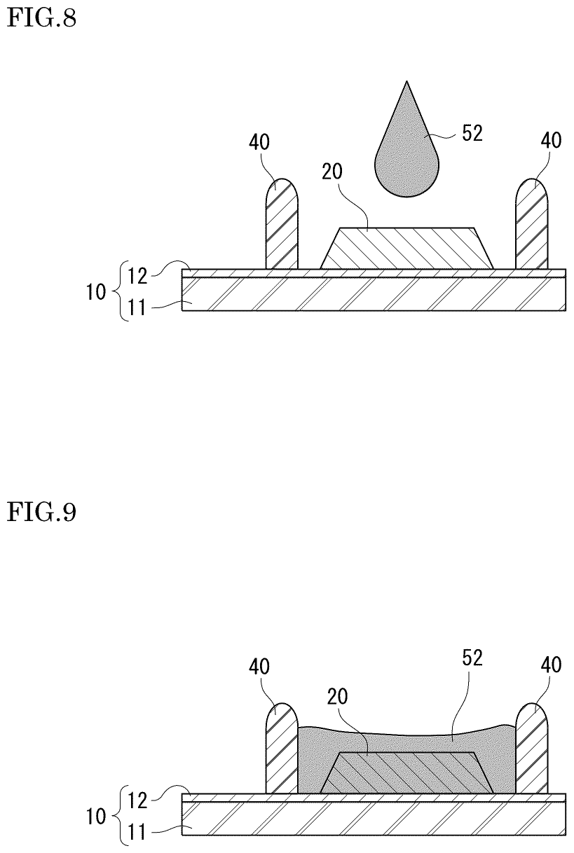

Embodiment 2 describes, as another method for producing the dye-sensitized solar cell 100, a production method using one-drop filling (ODF). FIGS. 8 and 9 are cross-sectional views schematically and sequentially illustrating steps of a method for producing a dye-sensitized solar cell according to Embodiment 2.

In the production method of Embodiment 2, as illustrated in FIG. 8, the porous semiconductor layer 20 and the sealing material 40 are formed on the electrode substrate 10. In this condition, the dye electrolyte solution 52 is delivered in droplets onto the porous semiconductor layer 20 within the frame of the sealing material 40. The amount of the dye electrolyte solution 52 to be delivered in droplets is the same as the amount of the dye electrolyte solution 52 to be eventually sealed in the cell of the dye-sensitized solar cell 100. The dye electrolyte solution 52 is the electrolyte solution 50 of Embodiment 1 with the dye further dissolved therein. That is, in Embodiment 2, a silane coupling agent is previously added to the dye electrolyte solution 52. The dye to be dissolved in the dye electrolyte solution 52 can be the same as the dye of the dye solution in Embodiment 1.

The dye electrolyte solution 52 to be added onto the porous semiconductor layer 20 additionally contains the silane coupling agent. Hence, as illustrated in FIG. 9, the dye electrolyte solution 52 quickly spreads over, and wets, the porous semiconductor layer 20. A conventional dye-sensitized solar cell, whose electrolyte solution does not contain the silane coupling agent, could be produced by ODF. However, the dye electrolyte solution without the silane coupling agent exhibits poor wettability and permeability with respect to the porous semiconductor layer. Hence, as to the conventional dye-sensitized solar cell, the dye electrolyte solution slowly spreads over, and wets, the porous semiconductor layer. That is why the dye is likely to be adsorbed unevenly onto the porous semiconductor layer 20 (the dye is adsorbed more onto a place where the dye electrolyte solution is first delivered in droplets). Such uneven adsorption of the dye causes a decrease in the power generation area of the porous semiconductor layer, and deteriorates the cell characteristics.

On the other hand, as to the dye-sensitized solar cell 100, the dye in the dye electrolyte solution 52 quickly spreads over, and wets, the porous semiconductor layer 20. Hence, the dye in the dye electrolyte solution 52 can uniformly spread over the entire porous semiconductor layer 20. Thanks to such a feature, the dye-sensitized solar cell 100 exhibits reduction in uneven adsorption of the dye onto the porous semiconductor layer 20, and improvement in cell characteristics.

The dye electrolyte solution 52 is delivered in droplets. After that, the counter-electrode substrate 60 is attached to the sealing material 40 to seal the dye electrolyte solution 52. Hence, the dye-sensitized solar cell 100 is obtained as seen in FIG. 6. That is, after the sealing with the counter electrode substrate 60, all (or almost all) of the dye contained in the dye electrolyte solution 52 is adsorbed onto the porous semiconductor layer 20. Hence, the dye electrolyte solution 52 becomes the electrolyte solution 50. Furthermore, the porous semiconductor layer 20 adsorbs the dye, and becomes the photoelectric conversion unit 70. Moreover, as seen in Embodiment 1, the silane coupling agent added to the dye electrolyte solution 52 forms a coating film on the porous semiconductor layer 20, thereby improving the cell characteristics of the dye-sensitized solar cell 100.

### Embodiment 3

Embodiment 3 will discuss a concentration of a silane coupling agent (a silane coupling agent concentration) in the electrolyte solution 50 (or in the dye electrolyte solution 52). Note that, in Embodiment, the silane coupling agent concentration is that of the electrolyte solution 50 at the moment when the electrolyte solution 50 is encapsulated in the region between the electrode substrate 10 and the counter-electrode substrate 60. Furthermore, in Embodiment 2, the silane coupling agent concentration is that of the dye electrolyte solution 52 at the moment when the dye electrolyte solution 52 is delivered in droplets onto the porous semiconductor layer 20.

First, if the silane coupling agent concentration of the electrolyte solution 50 is excessively low, the silane coupling agent cannot form a sufficient coating film on the porous semiconductor layer 20, so that the silane coupling agent hardly contributes to improvement in cell characteristics. In this regard, the silane coupling agent concentration of 5 vol % or more contributes to improvement in cell characteristics. The silane coupling agent concentration of 10 vol % provides almost optimum cell characteristics. In addition, if the silane coupling agent concentration is 10 vol % or more, further improvement in the cell characteristics is not particularly observed even though the silane coupling agent concentration is further raised. This is probably because when the silane coupling agent forms a sufficient coating film on the porous semiconductor layer 20, almost maximum cell characteristics can be obtained.

On the other hand, the silane coupling agent concentration of the electrolyte solution 50 also affects the solubility of the silane coupling agent and the wettability of the electrolyte solution 50. Specifically, if the silane coupling agent concentration of the electrolyte solution 50 increases, the permeability and the wettability of the electrolyte solution 50 increase with respect to the porous semiconductor layer 20, and the solubility of the silane coupling agent decreases in the solvent of the electrolyte solution.

Table 1 below shows a result of evaluating a relationship between: the silane coupling agent concentration of the electrolyte solution 50; and the solubility and the wettability.

TABLE 1

| | Silane Coupling Agent Concentration (Vol %) | | | | |
|---|---|---|---|---|---|
| | 5 | 10 | 20 | 30 | 50 |
| Solubility | CO | CO | CO | CO | NCO |
| Wettability | NOF | NOF | NOF | OF | OF |

(CO: Completely Soluble, NCO: Not Completely Soluble)
(NOF: No Overflow Observed, OF: Overflow Observed)

As to the solubility, the added silane coupling agent is completely soluble when the silane coupling agent concentration is in a range of 5 to 30 vol %. On the other hand, if the silane coupling agent concentration is 50 vol %, the silane coupling agent does not dissolve completely, and remains undissolved. Thus, in view of solubility, the silane coupling agent concentration is in a range of preferably 5 to 30 vol %.

Next, in view of wettability, the higher the silane coupling agent concentration is, the higher the wettability of the electrolyte solution 50 and the dye electrolyte solution 52 is. As described in Embodiment 2 above, if the ODF is used to produce the dye-sensitized solar cell 100, the wettability of the dye electrolyte solution 52 increases. Such a feature can reduce uneven adsorption of the dye onto the porous semiconductor layer 20. On the other hand, if the wettability of the dye electrolyte 52 is excessively high, the dye electrolyte solution 52 delivered in droplets might spread even over, and wet, the sealing material 40, and overflow an upper end face of the sealing material 40. If the silane coupling agent concentration is in a range of 5 to 20 vol %, the dye electrolyte solution 52 does not overflow the sealing material 40. However, if the silane coupling agent concentration is in a range of 30 to 50 vol %, the dye electrolyte solution 52 overflows the sealing material 40.

If the dye electrolyte solution 52 overflows the sealing material 40, the upper end surface of the sealing material 40 is contaminated by the dye electrolyte solution 52. When the counter electrode substrate 60 is attached to the electrode substrate 10, the adhesiveness decreases between the sealing material 40 and the counter electrode conductive layer 62 of the counter electrode substrate 60, and the resulting sealing reliability of the dye-sensitized solar cell 100 decreases. Furthermore, with the ODF, the dye electrolyte solution 52 is delivered in droplets in a precise amount in accordance with the amount of the dye electrolyte solution 52 sealed in the cell. However, if the dye electrolyte solution 52 overflows the sealing material 40, the amount of the dye electrolyte solution 52 to be sealed reduces accordingly. The resulting problem is that the adsorption amount of the dye onto the porous semiconductor layer 20 inevitably decreases. Thus, in view of wettability, and in particular, if the ODF is used to produce the dye-sensitized solar cell 100, the silane coupling agent concentration is within a range of preferably 5 to 20 vol %.

Note that if the dye-sensitized solar cell 100 is produced not by the ODF but by the method of Embodiment 1, the above problem does not occur even if the wettability of the electrolyte solution 50 is increased. Hence, in view of solubility, the silane coupling agent concentration is in a range of preferably 5 to 30 vol %.

### Embodiment 4

At least a portion of the silane coupling agent may undergo such a reaction as hydrolysis or conversion to a siloxane compound either in the electrolyte solution 50 or in the dye electrolyte solution 52. That is, the term “an electrolyte solution containing a silane coupling agent” in the present disclosure is a concept that the silane coupling agent is contained in the electrolyte solution as a reaction product of the silane coupling agent. The “electrolyte solution containing a silane coupling agent” may contain either a silane coupling agent or a reaction product of the silane coupling agent, or may contain both.

Furthermore, the silane coupling agent to be added either to the electrolyte solution 50 and to the dye electrolyte solution 52 may have the structure represented by the structural formula (1) as described above. Otherwise, the silane coupling agent may have any given structure. Preferably, the silane coupling agent has three alkoxy groups.

Having more alkoxy groups (hydrolyzable groups), the silane coupling agent can have more reaction points with, for example, metal oxide. That is, when the number of reaction points with the metal oxide increases, the silane coupling agent is likely to bond to, and to form a coating film on, the surface of the porous semiconductor layer 20. Furthermore, the water contained in the cell is used for a reaction to be caused when the silane coupling agent bonds to the surface of, for example, the metal oxide. The water in the cell is a factor to deteriorate performance, and leads to a decrease in reliability of the dye-sensitized solar cell 100. Preferably, the water is kept from the cell as much as possible. Hence, the silane coupling agent having a hydrolyzable group uses the water in the cell for the hydrolysis reaction. Such a feature has an advantageous effect of preventing deterioration of cell performance because of excessive water, thereby contributing to improvement in reliability. From this viewpoint, the number of alkoxy groups is preferably increased. However, if the silane coupling agent has many hydrolyzable groups, the solubility of the silane coupling agent decreases in the solvent of the electrolyte solution. Hence, when the silane coupling agent has the maximum number of hydrolyzable groups while exhibiting excellent solubility, the structure of the silane coupling agent has three hydrolyzable groups and one soluble group.

The embodiments disclosed here are examples in all respects, and do not provide a basis for a restrictive interpretation. Accordingly, the technical scope of the present disclosure is not to be interpreted solely by the embodiments described above, but to be defined in accordance with the recitations of the claims. Furthermore, all the modifications equivalent to the features of, and within the scope of, the claims are to be included within the technical scope of the present disclosure. While there have been described what are at present considered to be certain embodiments of the invention, it will be understood that various modifications may be made thereto, and it is intended that the appended claims cover all such modifications as fall within the true spirit and scope of the invention.

What is claimed is:

1. A dye-sensitized solar cell, comprising:
a first electrode including a porous semiconductor layer supporting a dye;
a second electrode serving as a counter electrode of the first electrode; and
an electrolyte solution filled between the first electrode and the second electrode,
wherein the electrolyte solution contains a silane coupling agent.

2. The dye-sensitized solar cell according to claim 1,
wherein, in the electrolyte solution, the silane coupling agent has a concentration in a range of 5 to 30 vol %.

3. The dye-sensitized solar cell according to claim 1,
wherein the silane coupling agent contained in the electrolyte solution has three alkoxy groups.

4. A method for producing a dye-sensitized solar cell including: a first electrode including a porous semiconductor layer supporting a dye; a second electrode serving as a counter electrode of the first electrode; and an electrolyte solution filled between the first electrode and the second electrode, the method comprising:
a step of sealing a region between the first electrode and the second electrode, using a sealing material; and
a step of encapsulating the electrolyte solution in the sealed region, the electrolyte solution containing a silane coupling agent.

5. The method for producing the dye-sensitized solar cell according to claim 4,
wherein, in the electrolyte solution to be encapsulated in the region, the silane coupling agent has a concentration in a range of 5 to 30 vol %.

6. A method for producing a dye-sensitized solar cell including: a first electrode including a porous semiconductor layer supporting a dye; a second electrode serving as a counter electrode of the first electrode; and an electrolyte solution filled between the first electrode and the second electrode, the method comprising:
a step of forming the porous semiconductor layer and a sealing material on a first substrate having the first electrode, the porous semiconductor layer not supporting the dye yet and the sealing material being formed into a shape of a frame;
a step of delivering a dye electrolyte solution in droplets onto the porous semiconductor layer within the frame of the sealing material, the dye electrolyte solution containing a dye to be supported on the porous semiconductor layer and a silane coupling agent; and
after the step of delivering the dye electrolyte solution, a step of attaching a second substrate to the sealing material to seal a region between the first electrode and the second electrode, the second substrate having the second electrode.

7. The method for producing the dye-sensitized solar cell according to claim 6,
wherein, in the dye electrolyte solution to be delivered onto the porous semiconductor layer, the silane coupling agent has a concentration in a range of 5 to 20 vol %.
